(19) United States
(12) Patent Application Publication
(10) Pub. No.: US 2020/0013590 A1
(43) Pub. Date: Jan. 9, 2020

(54) PROTECTIVE LAYER FOR CHUCKS DURING PLASMA PROCESSING TO REDUCE PARTICLE FORMATION

(71) Applicant: Tokyo Electron Limited, Tokyo (JP)

(72) Inventors: Eric Chih-Fang Liu, Albany, NY (US); Akiteru Ko, Albany, NY (US)

(21) Appl. No.: 16/460,730

(22) Filed: Jul. 2, 2019

Related U.S. Application Data
(60) Provisional application No. 62/694,641, filed on Jul. 6, 2018.
(60) Provisional application No. 62/732,235, filed on Sep. 17, 2018.

(51) Int. Cl. H01J 37/32; H01L 21/3213; H01L 21/02; H01L 21/687

(52) U.S. Cl. CPC H01J 37/32495; H01L 21/32136; H01L 21/0262; H01J 2237/335; H01J 2237/332; H01J 2237/3341; H01L 21/68757

(57) ABSTRACT

Embodiments are described herein to reduce formation of undesired particles during plasma processing for microelectronic workpieces by depositing a layer (e.g., think film) on the surface of a chuck, such as an electrostatic chuck (ESC), prior to plasma processing such as a plasma etch process (e.g., a reactive ion etch (RIE) process) and/or a plasma deposition process. This layer works as a lubricant or protective coating to reduce or minimize physical contact between the microelectronic workpiece (e.g., semiconductor wafer) and the chuck. This reduction in physical contact reduces scratching of the backside of the microelectronic workpiece and reduces related formation of undesired particles that can be transported to the front side of the microelectronic workpiece and cause defects and reduce yields. As such, the disclosed embodiments improve particle (PA) performance parameters for plasma etch and/or deposition processes.

### RELATED APPLICATIONS

This application claims priority to the following co-pending provisional applications: U.S. Provisional Patent Application Ser. No. 62/694,641, filed Jul. 6, 2018, entitled “PROTECTIVE COATING DURING ETCH PROCESSING,” and U.S. Provisional Patent Application Ser. No. 62/732,235, filed Sep. 17, 2018, entitled “PROTECTIVE LAYER FOR CHUCKS DURING PLASMA PROCESSING TO REDUCE PARTICLE FORMATION,” which are hereby incorporated by reference in their entirety.

### BACKGROUND

The present disclosure relates to methods for the manufacture of microelectronic workpieces, and in particular, methods to etch material layers on microelectronic workpieces.

Device formation within microelectronic workpieces typically involves a series of manufacturing techniques related to the formation, patterning, and removal of a number of layers of material on a substrate. To meet the physical and electrical specifications of current and next generation semiconductor devices, processing flows are being requested to reduce feature size while maintaining process quality parameters.

For advanced processing nodes, device minimization has become one primary conventional approach to reduce manufacturing costs by stacking more devices per unit area into microelectronic workpieces. As device critical dimensions have been pushed down to nanometer size, control of particle formation and reduction of particle impurities have become increasingly important to sustain desirable device performance and yield targets, particularly with respect to plasma etch processes.

FIG. 1A (Prior Art) provides an example embodiment 100 for a conventional plasma etch process using a chuck 108, such as an electrostatic chuck (ESC), to hold a microelectronic workpiece 106 within a processing chamber 102. For embodiment 100, a microelectronic workpiece 106, such as a semiconductor wafer, is being subjected to plasma processing as shown in view 122. The plasma processing can be, for example, a plasma etch process and/or a plasma deposition process performed within the processing chamber 102. As indicated by arrow 110, a temperature transition occurs during the plasma processing steps. During this temperature transition, undesired particles (PA) are generated from differences in thermal expansion as shown in view 124. These undesired particles can be transported to the front side of the microelectronic workpiece 106 and cause defects in the devices being formed.

Looking in more detail to view 122, the microelectronic workpiece 106 is coupled to the chuck 108 during the plasma process such as a plasma etch or deposition process. Where an ESC is used as the chuck 108, the microelectronic workpiece 106 is coupled to the ESC using an electrostatic charge induced on the ESC that holds the microelectronic workpiece 106 in place. During the plasma process, plasma gases are ignited to form plasma 104 within the processing chamber 102, and one or more etch and/or deposition steps are performed on the microelectronic workpiece 106.

Looking in more detail to view 124, it is shown that physical contact between the microelectronic workpiece 106 (e.g., wafer) and the chuck 108 (e.g., ESC) can cause formation of undesired particles, such as particle 134. In particular, particle formation often occurs during temperature transitions for plasma etch and/or deposition processes, such as reactive ion etch (RIE) processes, due to differences in thermal expansions coefficients for the materials within the microelectronic workpiece 106 and the chuck 108. As represented by box 120 and related arrows, the differences in thermal expansion during a temperature transition causes friction and/or movement between the backside of the microelectronic workpiece 106 and the front side of the chuck 108. Formation of undesired particles results from these conditions. For example, particle 134 can be formed by a scratch between the microelectronic workpiece 106 and the chuck 108.

Once formed, the undesired particles (PA) such as particle 134 can be transported within the processing chamber 102 to the front side of the microelectronic workpiece 106. This particle transfer onto the front side typically occurs in two ways. One is due to the application of an inert gas between the microelectronic workpiece 106 and the chuck 108 to improve thermal conductance. This inert gas will push particles, such as particle 134, into the processing chamber and these particles may fall onto the surface of the microelectronic workpiece 106. Another one is due to the pressure difference between the processing chamber and the gap between the chuck 108 and the microelectronic workpiece 106. Typically, this gap includes helium (He) gas having a pressure range of 1-5 Torr, while the processing chamber typically has a pressure range of 1-10 milli-Torr (mTorr). This pressure difference tends to transport particles, such as particle 134, from high pressure to low pressure. The transport of particles increases the number of particle impurities reaching the front side of the microelectronic workpiece 106. The resulting high PA counts lead to defects within the surface of the microelectronic workpiece 106 and to a reduction in device yields for the microelectronic workpieces being manufactured.

The formation of undesired particles such as particle 134 is shown in more detail with respect to box 130, which represents a portion the interaction between the backside of the microelectronic workpiece 106 and the front side of the chuck 108. As shown, uneven portions 132 of the surface of the chuck 108 can cause particle creation due to friction and movement with respect to the backside of the microelectronic workpiece 106. This friction and movement is increased during temperature transitions due to differences in thermal expansions coefficients for the materials within the microelectronic workpiece 106 and the chuck 108. Once formed, the undesired particles (PA) such as particle 134 can be transported within the processing chamber 102 to the front side of the microelectronic workpiece 106 as indicated by arrows 136.

FIG. 1B (Prior Art) shows an example representative embodiment 150 for high counts of undesired particles reaching the front side of a microelectronic workpiece 106 for the traditional etch process of FIG. 1A (Prior Art). For this example, about 162 particles were found to have impacted the surface of the microelectronic workpiece 106.

### SUMMARY

Embodiments are described herein to reduce formation of undesired particles during plasma processing for microelectronic workpieces by depositing a layer (e.g., think film) on the surface of a chuck, such as an electrostatic chuck (ESC), prior to plasma processing such as a plasma etch process (e.g., a reactive ion etch (ME) process) and/or a plasma deposition process. This layer works as a lubricant or protective coating to reduce or minimize physical contact between the microelectronic workpiece (e.g., semiconductor wafer) and the chuck. This reduction in physical contact reduces scratching of the backside of the microelectronic workpiece and reduces related formation of undesired particles that can be transported to the front side of the microelectronic workpiece and cause defects and reduce yields. As such, the disclosed embodiments improve particle (PA) performance parameters for plasma etch and/or deposition processes. Different or additional features, variations, and embodiments can also be implemented, and related systems and methods can be utilized as well.

For one embodiment, a method of processing microelectronic workpieces is disclosed including forming a layer on a surface of a chuck within a processing chamber, positioning a microelectronic workpiece on the surface of the chuck, and performing at least one of an etch process or a deposition process on the microelectronic workpiece.

In additional embodiments, the performing includes an etch process. In further embodiments, the etch process includes a plasma etch process. In still further embodiments, the plasma etch process includes a reactive ion etch (ME) process.

In additional embodiments, the performing includes a deposition process. In further embodiments, the deposition process includes a plasma deposition process.

In additional embodiments, the method also includes injecting an inert gas between the chuck and the microelectronic workpiece to facilitate thermal conductance. In additional embodiments, the chuck is an electrostatic chuck. In additional embodiments, the microelectronic workpiece is a semiconductor wafer.

In additional embodiments, the layer is configured to reduce contact between a backside of the microelectronic workpiece and the chuck. In further embodiments, the reduced contact results in fewer scratches in the backside of the microelectronic workpiece than would occur without the layer, and the scratches tend to form particles that can be transported to a front side of the microelectronic workpiece. In further embodiments, the method reduces particle count on the front side of the microelectronic workpiece by 1 to 80 percent by using the layer.

In additional embodiments, the forming includes depositing the layer using a deposition process. In further embodiments, the deposition process includes a plasma deposition process. In further embodiments, the layer includes a carbon-based film. In still further embodiments, the plasma deposition process uses a gas chemistry including at least one of the following: CF4, CH4, CH2F2, CO2, CO, CHF3, CH3F, C4F8, or C4F6. In other embodiments, the layer includes a silicon-based film. In further embodiments, the plasma deposition process uses a gas chemistry including SiCl4.

In additional embodiments, the performing includes one or more temperature transitions. In additional embodiments, the method further includes performing a clean process to remove the layer from the surface of the chuck.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A (Prior Art) provides an example embodiment for a plasma process using a chuck to hold a microelectronic workpiece within a processing chamber where differences in thermal expansion coefficients lead to increased formation of undesired particles.

FIG. 1B (Prior Art) shows an example representative embodiment for high counts of undesired particles reaching the front side of a wafer for the traditional etch process of FIG. 1A (Prior Art).

FIG. 2A provides an example embodiment where a protective layer is formed on a chuck within a process chamber prior to coupling a microelectronic workpiece to the chuck for plasma etch and/or deposition processing.

FIG. 2B shows an example representative embodiment for a reduction in undesired particles on the front side of a microelectronic workpiece achieved using the protective layer technique of FIG. 2A.

FIG. 3 is a process diagram of an example embodiment where a protective layer is formed on a chuck within a process chamber to reduce formation of undesired particles from backside scratching during plasma processing.

FIGS. 4A-D provide cross-section views of an example embodiment where a protective layer is formed on the surface of a chuck and used to reduce undesired particle generation during plasma processing.

### DETAILED DESCRIPTION

As described herein, a layer is deposited on the surface of a chuck, such as an electrostatic chuck (ESC), prior to using the chuck to hold a microelectronic workpiece during plasm processing such as plasma etch processing (e.g., RIE processing) and/or plasma deposition processing. This deposition of this additional material layer (e.g., thin film) on the chuck works as protective coating or lubricant to reduce or prevent physical contact and abrasion between the microelectronic workpiece (e.g., semiconductor wafer) and the chuck (e.g., ESC). This reduction in physical contact and related scratching of the backside of the wafer reduces the formation of undesired particles that can be transported to the front side of the wafer. This reduction in the number of undesired particles reduces defects and improves device yields. As such, the disclosed embodiments improve particle (PA) performance of plasma processes such as plasma etch processes, RIE processes, and/or deposition processes. Other advantages and implementations can also be achieved while still taking advantage of the process techniques described herein.

For etch processing chambers, it has been found that particle (PA) formation can be significantly increased during plasma etch processes, such as reactive ion etch (ME) processes, due to temperature transitions on the edge of a microelectronic workpiece such as a semiconductor wafer. Similar particular formation can also occur during plasma deposition processing. This undesired particle formation is mainly caused during temperature transitions due to differences in thermal expansion coefficients between materials for a microelectronic workpiece and materials for a chuck. For example, differences in thermal expansion coefficients often lead to wafer backside scratching during temperature transitions, and this scratching has been identified as leading to the formation of undesired particle impurities. In particular, wafer backside scratching leads to particle formation, and these particles are often transported from the backside of the wafer to the front side of the wafer. High counts of particle impurities generally degrade the defect performance on the front side of the wafer by increasing surface defects and decreasing device yields for the devices being manufactured. In addition, the wafer backside scratching and associated particle formation also tends to introduce contamination to wafer transferring modules and thereby tends to introduce contamination to additional processing equipment that follows the plasma etch/deposition processing equipment.

For the embodiments described herein, physical contact to and scratching of the backside of the microelectronic workpiece (e.g., semiconductor wafer) is reduced. As such, the formation of undesired particles and the transport of these particle impurities to the front side of the microelectronic workpiece is also reduced. As described herein, this reduction in particle impurities is achieved through formation of a layer, such as a thin film, on the surface of the chuck (e.g., ESC) prior to performing the plasma etch/deposition process. This layer works as a lubricant or protective coating to minimize the physical contact between the microelectronic workpiece and the chuck thereby reducing or eliminating the formation of undesired particles due to scratching of the backside of the microelectronic workpiece. This reduction in particle counts results in significant improvements to particle performance parameters by reducing defects and increasing device yields for the microelectronic workpieces being manufactured using plasma etch/deposition processes.

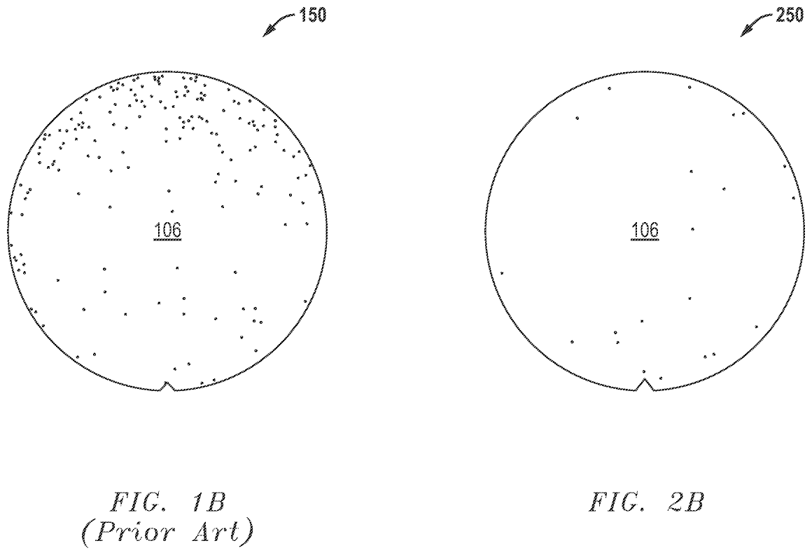

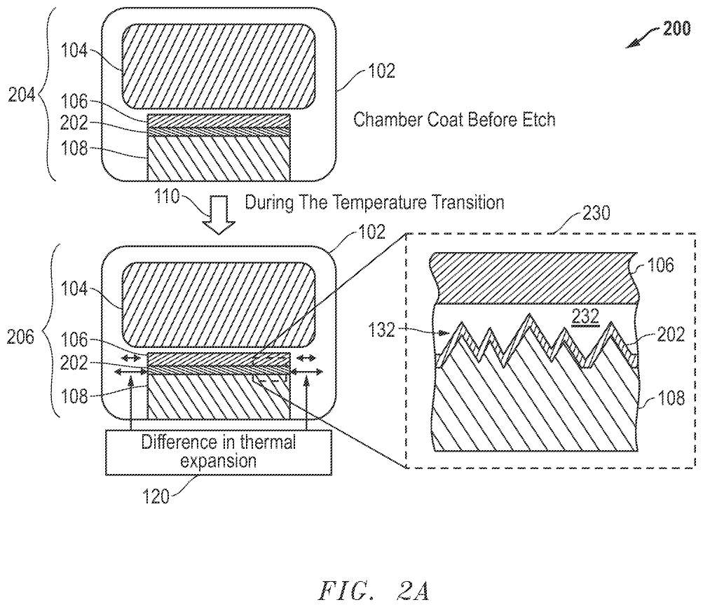

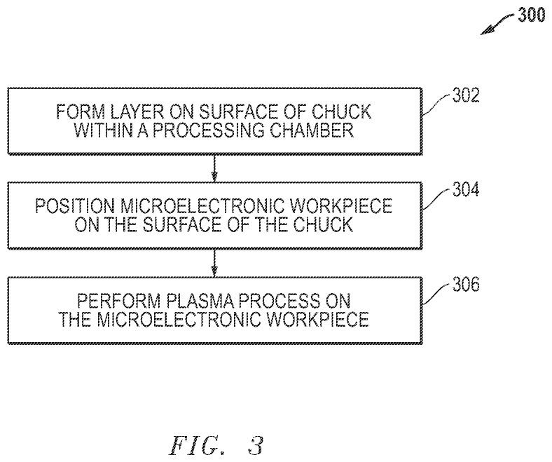

FIG. 2A provides an example embodiment 200 where a protective layer 202 is formed on the chuck 108 prior to coupling the microelectronic workpiece 106 to the chuck 108 for the plasma etch and/or deposition processing. For example, a thin film can be deposited onto the surface of the chuck 108 using a plasma deposition process. After the formation of the protective layer 202, the microelectronic workpiece 106 is coupled to the chuck 108.

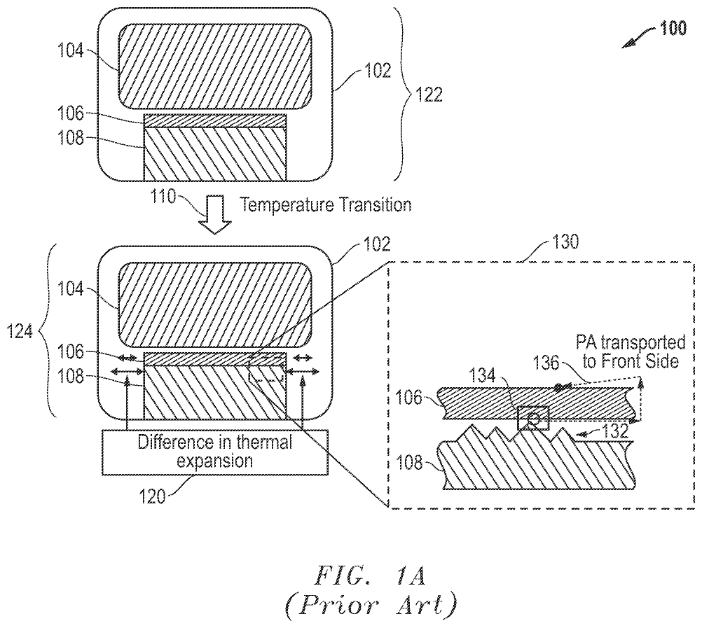

For embodiment 200, a microelectronic workpiece 106, such as a semiconductor wafer, is being subjected to plasma processing as shown in view 204. The plasma processing can be, for example, a plasma etch process and/or a plasma deposition process performed within the processing chamber 102. As indicated by arrow 110, a temperature transition occurs during the plasma processing steps. During this temperature transition as shown in view 206, the formation of undesired particles is greatly reduced or eliminated due to the protective layer 202 as compared to the prior solutions in FIG. 1A (Prior Art).

Looking in more detail to view 204, the microelectronic workpiece 106 is coupled to the chuck 108 during the plasma processing such as a plasma etch process (e.g., ME process) and/or plasma deposition process. Where an ESC is used as the chuck 108, the microelectronic workpiece 106 is coupled to the ESC using an electrostatic charge induced on the ESC that holds the microelectronic workpiece 106 in place. During the plasma etch/deposition process, plasma gases are ignited to form plasma 104 within the processing chamber 102, and one or more etch and/or deposition process steps are performed on the microelectronic workpiece 106.

Looking in more detail to view 206, it is shown that physical contact between the microelectronic workpiece 106 (e.g., wafer) and the chuck 108 (e.g., ESC) is reduced by formation of the protective layer 202. In particular, particle formation that often occurred with prior solutions during temperature transitions for plasma processes is greatly reduced or eliminated despite differences in thermal expansions coefficients for the materials within the microelectronic workpiece 106 and the chuck 108. As represented by box 120 and related arrows, differences in thermal expansion during a temperature transition still exist but particle formation is suppressed by the protective layer 202. The resulting low particle (PA) counts lead to reduced defects within the surface of the microelectronic workpiece 106 and improved device yields for the microelectronic workpieces being manufactured.

As described herein, the layer 202 acts as a protective coating to reduce the formation of undesired particles due to physical contact between the microelectronic workpiece 106 and the chuck 108. For example, during temperatures transitions, backside scratching of the microelectronic workpiece 106 due to differences in thermal expansion coefficients is reduced by the presence of the protective layer 202. The particle count for undesired particles is therefore greatly reduced as compared to the traditional process. This low particle count leads to reduced defects due to particle impurities and increased device yields. For example, it has been found that 1 to 80 percent reduction in particle counts on the front side of a microelectronic workpiece can be achieved through the deposition of the protective layer 202 on the chuck 108 prior to plasma processing as compared to traditional processes.

A representation of the reduction in formation of undesired particles is shown in more detail in call-out box 230, which represents a portion the interaction between the backside of the microelectronic workpiece 106 and the front side of the chuck 108. As shown, the protective layer 202 effectively protects the backside of the microelectronic workpiece 106 from being scratched by the uneven portions 132 of the surface of the chuck 108. Thus, even though relative movement between the chuck 108 and the microelectronic workpiece 106 is increased during temperature transitions due to differences in thermal expansions coefficients, undesired particle formation is reduced or eliminated.

It is further noted that an inert gas such as helium (He) is usually injected in the gap between the microelectronic workpiece 106 and the chuck 108. As such, an inert gas 232 (e.g. He) is expected to be in the gap between the protective layer 202 and the microelectronic workpiece 106. This inert gas 232 is used to maintain the thermal conductance between the chuck 108 and the microelectronic workpiece 106. Due to this purpose, a high-pressure condition for this inert gas 232 is expected.

FIG. 2B shows an example representative embodiment for the reduction in undesired particles on the front side of a microelectronic workpiece 106 achieved using the protective layer technique described herein to reduce physical contact and backside scratching for the microelectronic workpiece 106. For this example, about 44 particles were found to have impacted the surface of the microelectronic workpiece 106. This a 27% reduction in the total number of particles as compared to the prior solution of FIG. 1B (Prior Art).

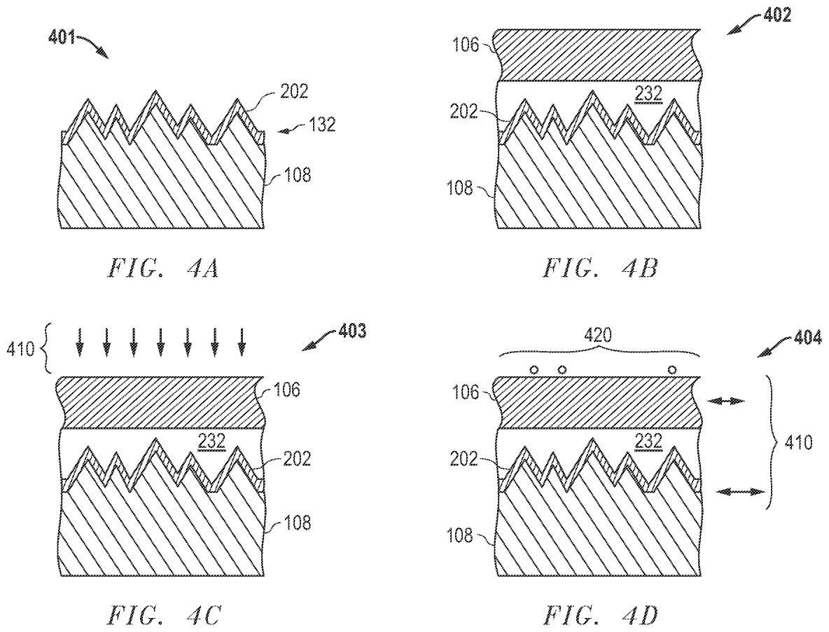

FIG. 3 is a process diagram of an example embodiment 300 where a protective layer is used to reduce formation of undesired particles from backside scratching during plasma processing. In block 302, a layer is formed on the surface of a chuck within a processing chamber. In block 304, a microelectronic workpiece is positioned on the surface of the chuck. For example, where an ESC is used as the chuck, the microelectronic workpiece is coupled to the ESC using an electrostatic charge induced on the ESC that holds the microelectronic workpiece in place. In block 306, a plasma process is performed on the microelectronic workpiece. For one embodiment, the plasma process is a plasma etch process such as an RIE process and/or other etch process. For one embodiment, the plasma process is a deposition process. Further, the plasma etch and/or deposition processes can include one or more temperature transitions. Additional and/or different process steps can also be used while still taking advantage of the process techniques described herein.

By forming the protective layer over the chuck, the disclosed embodiments reduce contact between the backside of a substrate for a microelectronic workpiece and the chuck. As described herein, this reduced contact results in fewer scratches in the backside of the substrate during temperature transitions. In contrast, backside scratching during temperature transitions for prior solutions caused formation of particles that were often transported to the front side of the substrate thereby increasing defects. The methods described herein are configured to reduce particle count from 1 to 80 percent as compared to methods that do not include the protective layer formed on the chuck prior to plasma processing. Other features and advantages can also be achieved using the techniques described herein that form a protective layer between the microelectronic workpiece and the chuck.

FIGS. 4A-D provide cross-section views of an example embodiment where a layer 202 is formed on the surface of a chuck 108 within a processing chamber. As described herein, this layer 202 provides a protective coating between the chuck 108 and a microelectronic workpiece 106 thereby reducing undesired particle generation during etch/deposition processing.

FIG. 4A provides a cross-section view of an example embodiment 401 where a layer 202 is formed on the surface of the chuck 108 to provide a lubricant or protective coating. In part, the protective layer 202 also effectively smooths out and covers the rough/uneven surface 132 for the chuck 108. For one example embodiment, before the actual plasma process is performed, a selected gas chemistry is injected into the processing chamber, and plasma assisted deposition of a thin film is performed to form the protective layer 202 on the surface of the chuck 108 (e.g., ESC). This thin film or other material layer can also be deposited on the processing chamber in addition to the formation of the protective layer 202 on the chuck 108. As described herein, this protective layer 202 works as protective coating or lubricant to reduce or prevent physical contact and/or abrasion between the wafer and the ESC.

For one embodiment, the protective layer 202 is deposited on the surface of the chuck 108 (e.g., ESC) by a plasma deposition process and plasma gas chemistries to deposit protective layers such as carbon-based films, silicon-based films, and/or other protective films. Gas chemistries used to form carbon-based films can include one or more of the following: CF₄, CH₄, CH₂F₂, CO₂, CO, CHF₃, CH3_{F}, C₄F₈, C₄F₆, and/or other desired carbon-containing compounds or gasses. Further, additional gases can be included within the gas chemistries for formation of carbon-based films such as one or more of the following: SF₆, SO₂, O₂, Ar, He, N₂, Cl₂, HBr, NF₃, and/or other compounds or gases. Gas chemistries used to form silicon-based films can include one or more of the following: SiCl₄ and/or other desired silicon-containing compounds or gasses. Further, additional gases can be included within gas chemistries for formation of silicon-based films such as one or more of the following: CF₄, CH₂F₂, SF₆, CO₂, CO, O₂, Ar, He, N₂, CHF₃, CH₃F, Cl₂, HBr, C₄F₈, C₄F₆, NF₃, and/or other desired compounds or gasses.

FIG. 4B provides a cross-section view of an example embodiment 402 where a microelectronic workpiece 106 is coupled to the chuck 108 within the processing chamber. For example, after the layer 202 is formed on the chuck 108, a microelectronic workpiece 106 can be moved into the processing chamber, coupled to the chuck 108, and prepared for the plasma processing. Where the chuck 108 is an ESC, the microelectronic workpiece 106 is also electrostatically coupled to and held by the chuck 108. As described herein, however, the microelectronic workpiece 106 is physically sitting on top of the layer 202, such as a deposited thin film, which works as a lubricant or protective coating. Further, an inert gas such as helium (He) is usually injected in the gap between the microelectronic workpiece 106 and the chuck 108. As such, an inert gas 232 (e.g. He) is expected to be in the gap between the protective layer 202 and the microelectronic workpiece 106. This inert gas 232 is used to maintain the thermal conductance between the chuck 108 and the microelectronic workpiece 106. Due to this purpose, a high-pressure condition for this inert gas 232 is expected.

FIG. 4C provides a cross-section view of an example embodiment 403 where the microelectronic workpiece 106 is subjected to plasma processing as indicated by arrows 410. As described herein, the layer 202 works as a protective coating to reduce or prevent physical contact between the microelectronic workpiece 106 and the surface of the chuck 108 thereby reducing or minimizing the scratches to the backside of the microelectronic workpiece 106. These scratches can occur, for example, due to differences in expansion coefficients during temperature transitions for the plasma processing indicated by arrows 410. By reducing or minimizing the scratches, the number of particles formed from physical contact between the microelectronic workpiece 106 and the chuck 108 is reduced.

FIG. 4D provides a cross-section view of an example embodiment 404 where undesired particles 420 have been reduced on the front side of the microelectronic workpiece 106. As described herein, the reduction in the formation of undesired particles from backside scratching significantly reduces the number of particles transported to the front side of the microelectronic workpiece 106. The reduction in number or particle count for undesired particle 420 reaching the front side of the microelectronic workpiece 106 reduces defects and improves yields.

It is noted that FIGS. 4A-D provide one example embodiment, and additional and/or different process steps could also be used. For example, after processing of the microelectronic workpiece 106, an additional chamber clean process can also be used to remove the material layer 202 (e.g., thin film) and reset the chamber condition for the processing of following microelectronic workpieces. For example, this chamber clean process can be used to remove a deposited thin film from the surface of the chuck 108 and/or from the processing chamber depending upon what was deposited. This chamber clean process procedure can be repeated for each processed microelectronic workpiece 106. Other variations can also be implemented while still taking advantage of the techniques described herein.

It is noted that one or more deposition processes can be used to form the material layers described herein. For example, one or more depositions can be implemented using chemical vapor deposition (CVD), plasma enhanced CVD (PECVD), physical vapor deposition (PVD), atomic layer deposition (ALD), and/or other deposition processes. For a plasma deposition process, a precursor gas mixture can be used including but not limited to hydrocarbons, fluorocarbons, or nitrogen containing hydrocarbons in combination with one or more dilution gases (e.g., argon, nitrogen, etc.) at a variety of pressure, power, flow and temperature conditions. Lithography processes with respect to PR layers can be implemented using optical lithography, extreme ultra-violet (EUV) lithography, and/or other lithography processes. The etch processes can be implemented using plasma etch processes, discharge etch processes, and/or other desired etch processes. For example, plasma etch processes can be implemented using plasma containing fluorocarbons, oxygen, nitrogen, hydrogen, argon, and/or other gases. In addition, operating variables for process steps can be controlled to ensure that CD target parameters for vias are achieved during via formation. The operating variables may include, for example, the chamber temperature, chamber pressure, flowrates of gases, frequency and/or power applied to electrode assembly in the generation of plasma, and/or other operating variables for the processing steps. Variations can also be implemented while still taking advantage of the techniques described herein.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of processing microelectronic workpieces, comprising:
forming a layer on a surface of a chuck within a processing chamber;
positioning a microelectronic workpiece on the surface of the chuck; and
performing at least one of an etch process or a deposition process on the microelectronic workpiece.

2. The method of claim 1, wherein the performing comprises an etch process.

3. The method of claim 2, wherein the etch process comprises a plasma etch process.

4. The method of claim 3, wherein the plasma etch process comprises a reactive ion etch (RIE) process.

5. The method of claim 1, wherein the performing comprises a deposition process.

6. The method of claim 5, wherein the deposition process comprises a plasma deposition process.

7. The method of claim 1, further comprising injecting an inert gas between the chuck and the microelectronic workpiece to facilitate thermal conductance.

8. The method of claim 1, wherein the chuck is an electrostatic chuck.

9. The method of claim 1, wherein the microelectronic workpiece is a semiconductor wafer.

10. The method of claim 1, wherein the layer is configured to reduce contact between a backside of the microelectronic workpiece and the chuck.

11. The method of claim 10, wherein the reduced contact results in fewer scratches in the backside of the microelectronic workpiece than would occur without the layer, the scratches tending to form particles that can be transported to a front side of the microelectronic workpiece.

12. The method of claim 10, wherein the method reduces particle count on the front side of the microelectronic workpiece by 1 to 80 percent by using the layer.

13. The method of claim 1, wherein the performing comprises one or more temperature transitions.

14. The method of claim 1, wherein the forming comprises depositing the layer using a deposition process.

15. The method of claim 14, wherein the deposition process comprises a plasma deposition process.

16. The method of claim 15, wherein the layer comprises a carbon-based film.

17. The method of claim 16, wherein the plasma deposition process uses a gas chemistry comprising at least one of the following: CF₄, CH₄, CH₂F₂, CO₂, CO, CHF₃, CH3_{F}, C₄F₈, or C₄F₆.

18. The method of claim 14, wherein the layer comprises a silicon-based film.

19. The method of claim 18, wherein the plasma deposition process uses a gas chemistry comprising SiCl₄.

20. The method of claim 1, further comprising performing a clean process to remove the layer from the surface of the chuck.
